(19) United States
(12) Patent Application Publication
(10) Pub. No.: US 2023/0103894 A1
(43) Pub. Date: Apr. 6, 2023

(54) HIGH-FREQUENCEY PACKAGE, HIGH-FREQUENCY MODULE, AND RADIO WAVE ABSORPTION METHOD

(71) Applicant: NEC Corporation, Tokyo (JP)

(72) Inventor: Yuki YOSHIMURA, Tokyo (JP)

(73) Assignee: NEC Corporation, Tokyo (JP)

(21) Appl. No.: 17/949,415

(22) Filed: Sep. 21, 2022

(30) Foreign Application Priority Data
Oct. 4, 2021 (JP) 2021-163459

(51) Int. Cl. H01L 23/552; H01L 23/66; H01L 23/00; H01Q 1/52

(52) U.S. Cl. CPC H01L 23/552; H01L 23/66; H01L 24/32; H01Q 1/526; H01L 2223/6688; H01L 2223/6644; H01L 2224/32225; H01L 2924/3025; H01L 2924/2027; H01L 2924/1421; H01L 2924/1611; H01L 2924/16151; H01L 2924/1616; H01L 2924/16195; H01L 2924/16251; H01L 2924/1631; H01L 2924/16315; H01L 2924/1632

(57) ABSTRACT

A high-frequency package includes a radio wave shielding portion that shields radio waves radiated from a high-frequency component, a radio wave absorber that is arranged facing the high-frequency component and that absorbs the radio waves, and an adjusting means that enables adjustment of distance from the radio wave absorber to the high-frequency component by adjusting a position of the radio wave absorber with respect to the radio wave shielding portion.

This application is based upon and claims the benefit of priority from Japanese patent application No. 2021-163459, filed Oct. 4, 2021, the disclose of which is incorporated herein in its entirety by reference.

### TECHNICAL FIELD

The disclosure relates to a high-frequency package, a high-frequency module and a radio wave absorption method.

### BACKGROUND ART

For example, Patent Document 1 (Japanese Unexamined Patent Application Publication No. 2000-165084) discloses a high-frequency package having a radio wave absorber. Such a high-frequency package includes a housing that prevents the emission of unnecessary radio waves to the outside or the reception of unnecessary radio waves from the outside. However, in a high-frequency module provided with such a high-frequency package, a feedback loop from the output end to the input end may be formed due to the reflection of radio waves within the housing, and input/output isolation may not be obtained. If isolation cannot be achieved, unnecessary oscillation will occur whereby the characteristics of high-frequency components cannot be fully exploited. Therefore, for example, as disclosed in Patent Document 1, it is common that a radio wave absorber formed with a magnetic material be attached to the upper part of a high-frequency component inside a housing.

### SUMMARY

An example object of this disclosure is to provide a high-frequency package, a high-frequency module, and a radio wave absorption method capable of improving the radio wave absorption characteristic by making it possible to adjust the distance from a high-frequency component to a radio wave absorber.

The high-frequency package, which is one aspect of the present disclosure, includes a radio wave shielding portion that shields radio waves radiated from a high-frequency component, a radio wave absorber that is arranged facing the high-frequency component and that absorbs the radio waves, and an adjusting means that enables adjustment of distance from the radio wave absorber to the high-frequency component by adjusting a position of the radio wave absorber with respect to the radio wave shielding portion.

The radio wave absorbing method according to one aspect of the present disclosure includes adjusting distance from a radio wave absorber that absorbs radio waves to a high-frequency component by adjusting a position of the radio wave absorber with respect to a radio wave shielding portion that shields the radio waves radiated from the high-frequency component.

### BRIEF DESCRIPTION OF THE DRAWINGS

FIG. 1A is a plan view of a schematic outline block diagram of the high-frequency module according to the first embodiment of the present disclosure.

FIG. 1B is a vertical sectional view of a schematic outline block diagram of the high-frequency module according to the first embodiment of the present disclosure.

FIG. 2 is an explanatory diagram showing the assembly process of the high-frequency module according to the first embodiment of the present disclosure.

FIG. 3 is an explanatory diagram showing the assembly process of the high-frequency module according to the first embodiment of the present disclosure.

FIG. 4 is an explanatory diagram showing the assembly process of the high-frequency module according to the first embodiment of the present disclosure.

FIG. 5A is a plan view of the schematic outline block diagram of the high-frequency module according to the second embodiment of the present disclosure.

FIG. 5B is a vertical sectional view of the schematic outline block diagram of the high-frequency module according to the second embodiment of the present disclosure.

FIG. 6A is a plan view of the schematic outline block diagram of the high-frequency module according to the third embodiment of the present disclosure.

FIG. 6B is a vertical sectional view of a schematic outline block diagram of the high-frequency module according to the third embodiment of the present disclosure.

FIG. 7A is a plan view of a schematic outline block diagram of the high-frequency module according to the fourth embodiment of the present disclosure.

FIG. 7B is a vertical sectional view of a schematic outline block diagram of the high-frequency module according to the fourth embodiment of the present disclosure.

FIG. 8 is a schematic outline block diagram of the high-frequency module according to the fifth embodiment of the present disclosure.

### EXAMPLE EMBODIMENT

Hereinbelow, embodiments of the high-frequency package, the high-frequency module, and the radio wave absorbing method according to the present disclosure will be described with reference to the drawings.

### First Embodiment

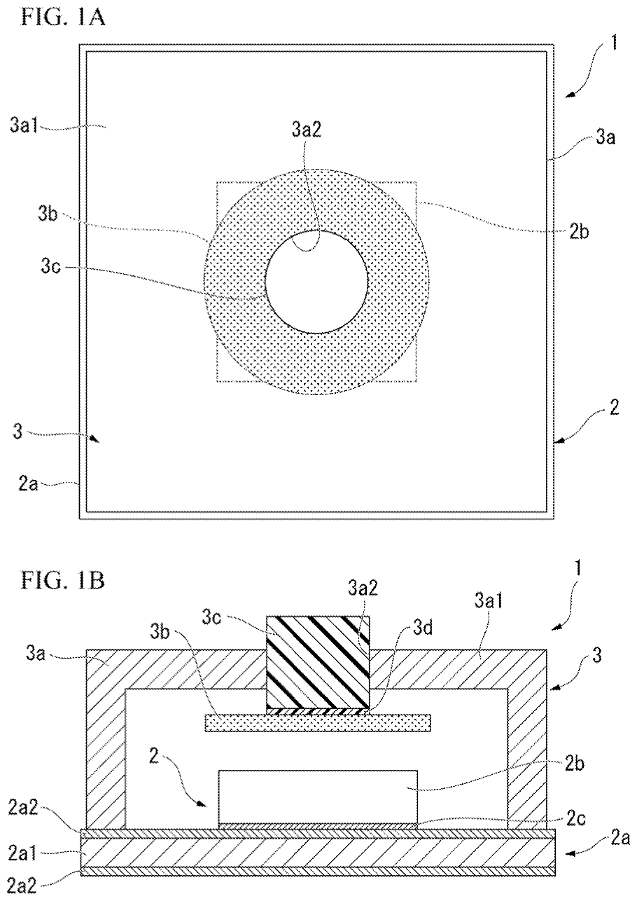

FIGS. 1A and 1B are schematic outline block diagrams of a high-frequency module 1 of the present embodiment. FIG. 1A is a plan view and FIG. 1B is a vertical sectional view.

The high-frequency module 1 of the present embodiment is a device that handles high-frequency (for example, a frequency higher than 10 kHz) electrical signals. The high-frequency module 1 of this embodiment is provided with an electronic substrate 2 and a high-frequency package 3.

In the following description, for convenience of explanation, the arrangement direction of the electronic substrate 2 and the high-frequency package 3 is referred to as a vertical direction. However, the installation orientation of the high-frequency module 1 is not limited thereto.

The electronic substrate 2 is provided with a printed wiring substrate 2a (substrate) and a high-frequency amplifier 2b (high-frequency component). The printed wiring substrate 2a is provided with a dielectric layer 2a1 and a conductor layer 2a2.

As the printed wiring substrate 2a, for example, as shown in FIG. 1B, a double-sided substrate in which the conductor layer 2a2 is provided on both sides of the single dielectric layer 2a1 can be used. Further, as the printed wiring substrate 2a, it is also possible to use a single-sided substrate in which the conductor layer is provided on one side of the dielectric layer or a multilayer substrate in which the conductor layer is contained inside the dielectric layer.

The high-frequency amplifier 2b is a high-frequency component mounted on the printed wiring substrate 2a. The high-frequency amplifier 2b amplifies the input high-frequency electrical signal into a signal having a larger voltage or power. For example, the high-frequency amplifier 2b amplifies an electrical signal input from a specific pattern formed by the conductor layer 2a2 of the printed wiring substrate 2a, and outputs the electrical signal via another pattern. For example, as shown in FIG. 1B, such a high-frequency amplifier 2b is joined to the printed wiring substrate 2a using solder 2c.

The high-frequency package 3 is a component that prevents radio waves originating from the high-frequency amplifier 2b from being radiated to the outside and prevents external radio waves from reaching the high-frequency amplifier 2b. The high-frequency package 3 is provided with a housing 3a (radio wave shielding portion), a radio wave absorber 3b, and a resin support portion 3c (adjusting means).

The housing 3a is formed of, for example, metal, and is a radio wave shielding portion that shields radio waves. In the present embodiment, the housing 3a is formed in a container shape with an open lower end. The housing 3a is fixed to a part of the printed wiring substrate 2a so that the high-frequency amplifier 2b is housed inside. That is, the high-frequency amplifier 2b is covered with the housing 3a from the upward and the directions orthogonal to vertical directions. The housing 3a is joined to the printed wiring substrate 2a using, for example, a joining material (not shown).

As shown in FIG. 1A, the housing 3a is formed in a rectangular shape, for example, when viewed from above. However, as the shape seen from above the housing 3a, any shape, such as circular or polygonal, can be adopted.

The upper wall 3a1 of the housing 3a is provided with a through hole 3a2 that passes through in the vertical direction. The through hole 3a2 is an opening into which the resin support portion 3c is press-fitted. The through hole 3a2 is arranged at a position overlapping the high-frequency amplifier 2b when viewed from above, for example. For example, when viewed from above, the through hole 3a2 is arranged so that the center thereof overlaps the center of the high-frequency amplifier 2b. The resin support portion 3c press-fitted into the through hole 3a2 passes through the upper wall 3a1 of the housing 3a in the vertical direction and is held by the upper wall 3a1 of the housing 3a.

The radio wave absorber 3b is arranged to face the high-frequency amplifier 2b and thereby absorbs radio waves. In the present embodiment, the radio wave absorber 3b is arranged above the high-frequency amplifier 2b, and is arranged facing the high-frequency amplifier 2b from above. The radio wave absorber 3b is formed by using a magnetic material. The radio wave absorber 3b is formed so that the shape in plan view is circular, for example, as shown in FIG. 1A, and is formed in a plate shape, for example, with the front and back surfaces facing in the vertical direction as shown in FIG. 1B.

The size of the radio wave absorber 3b in plan view is wider than that of the through hole 3a2 of the housing 3a. Therefore, the radio wave absorber 3b, by covering the entire through hole 3a2 from below, can prevent radio waves from being incident on the through hole 3a2 from the inside of the housing 3a. Therefore, it is possible to prevent radio waves from being emitted from the inside of the housing 3a to the outside of the housing 3a through the through hole 3a2.

The resin support portion 3c is a resin portion that is press-fitted into the through hole 3a2 provided in the housing 3a and to which the radio wave absorber 3b is fixed. The resin support portion 3c is cylindrical and is formed so as to be compressible and deformable in the radial direction. The diameter of the resin support portion 3c is the same as or slightly larger than the diameter of the through hole 3a2 in a state where no external force is applied.

Such a resin support portion 3c is formed by using a resin material having a Young's modulus enabling compression and deformation of the resin to an extent allowing insertion into the through hole 3a2. Therefore, by compressing and deforming the resin support portion 3c in the radial direction, it is possible to move the resin support portion 3c in the vertical direction while being inserted into the through hole 3a2. Further, when the pressing by the external force that is exerting compression and deformation is stopped, the resin support portion 3c comes into close contact with the inner wall surface of the through hole 3a2 based on the restoring force, and is held by the inner wall surface of the through hole 3a2, that is, the housing 3a.

The lower end of the resin support portion 3c is arranged below the upper wall 3a1 of the housing 3a and above the high-frequency amplifier 2b. The radio wave absorber 3b is fixed to the lower end of the resin support portion 3c via an adhesive layer 3d. That is, the radio wave absorber 3b is arranged below the upper wall 3a1 of the housing 3a and above the high-frequency amplifier 2b in a state of being fixed to the lower end of the resin support portion 3c.

The resin support portion 3c, by being compressed and deformed in a state of being inserted into the through hole 3a2, is moved in the vertical direction. At the same time, the radio wave absorber 3b fixed to the lower end of the resin support portion 3c is moved with respect to the upper wall 3a1 of the housing 3a. As a result, the distance from the radio wave absorber 3b to the high-frequency amplifier 2b changes. Further, the position of the radio wave absorber 3b with respect to the upper wall 3a1 is fixed by stopping the pressing by the external force that is exerting the compression and deformation. As a result, the distance from the radio wave absorber 3b to the high-frequency amplifier 2b is fixed. That is, the resin support portion 3c can adjust the distance from the radio wave absorber 3b to the high-frequency amplifier 2b by adjusting the position of the radio wave absorber 3b with respect to the housing 3a.

The resin support portion 3c can be formed by using, for example, polytetrafluoroethylene. By forming the resin support portion 3c using polytetrafluoroethylene, the frictional force generated between the resin support portion 3c and the housing 3a is reduced, and the resin support portion 3c can be easily moved up and down. Further, the resin support portion 3c can also be formed by using, for example, a material having a radio wave absorbing component. By forming the resin support portion 3c using the material having the radio wave absorbing component, it is possible to more reliably suppress the passage of radio waves through the through hole 3a2. It is also possible to form the resin support portion 3c by dispersing the material having the radio wave absorbing component.

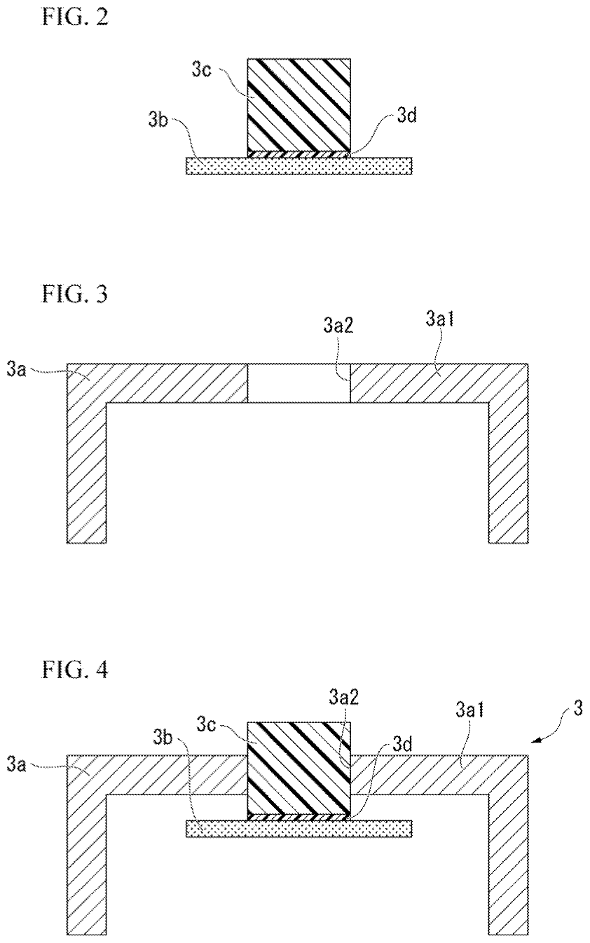

An example of an assembly method of the high-frequency module 1 will be described. As shown in FIG. 2, the radio wave absorber 3b is fixed to the lower end of the resin support portion 3c by using the adhesive layer 3d. Further, as shown in FIG. 3, the through hole 3a2 matching the shape of the resin support portion 3c is formed in the upper wall 3a1 of the housing 3a. With regard to the order of the process shown in FIG. 2 and the process shown in FIG. 3, either one may be first. Further, the step shown in FIG. 2 and the step shown in FIG. 3 may be performed in parallel. Subsequently, as shown in FIG. 4, the resin support portion 3c is press-fitted into the through hole 3a2 from below the housing 3a, and the resin support portion 3c and the radio wave absorber 3b are fixed to the housing 3a. By performing such steps shown in FIGS. 2 to 4, the high-frequency package 3 is assembled.

Subsequently, the high-frequency package 3 assembled in this way is fixed to the electronic substrate 2. At this time, the high-frequency package 3 is arranged so that the high-frequency amplifier 2b is housed inside the housing 3a and the radio wave absorber 3b is arranged above the high-frequency amplifier 2b.

Subsequently, by grasping the portion of the resin support portion 3c protruding upward from the upper wall 3a1 with a jig or fingers to move the resin support portion 3c in the vertical direction, the interval (distance) between the radio wave absorber 3b and the high-frequency amplifier 2b is adjusted. At this time, the interval (distance) between the radio wave absorber 3b and the high-frequency amplifier 2b is adjusted so that a high absorption characteristic of radio waves is achieved by the radio wave absorber 3b. The distance between the high-frequency amplifier 2b and the radio wave absorber 3b for obtaining the high absorption characteristic of radio waves depends on the frequency of the high-frequency amplifier 2b, but may also depend on the shape of the housing 3a and the size of other parts. Therefore, it is preferable to determine the position of the radio wave absorber 3b by trial several times.

That is, in the present embodiment, a radio wave absorption method is performed that adjusts the distance from the radio wave absorber 3b to the high-frequency amplifier 2b by adjusting the position of the radio wave absorber 3b, which absorbs radio waves, with respect to the housing 3a that shields radio waves radiated from the high-frequency amplifier 2b.

In such a high-frequency module 1 of the present embodiment, it is possible to change the operating frequency by exchanging only the high-frequency amplifier 2b while using the same metal housing 3a. Even in such a case, a design is possible that unleashes the characteristics of the high-frequency amplifier 2b by changing the distance between the high-frequency amplifier 2b and the radio wave absorber 3b.

Further, since the same housing 3a (that is, the same high-frequency package 3) can be used before and after the change of the high-frequency amplifier 2b, the redesign costs can be reduced. Also, since the distance between the high-frequency amplifier 2b and the radio wave absorber 3b can be adjusted from the outside of the housing 3a, whereby the performance of the high-frequency amplifier 2b can be maximized, there will be brought about an enhancement of the performance of the high-frequency module 1.

The high-frequency package 3 of the present embodiment as described above is provided with the housing 3a, the radio wave absorber 3b, and the resin support portion 3c. The housing 3a shields radio waves radiated from the high-frequency amplifier 2b.

The radio wave absorber 3b is arranged facing the high-frequency amplifier 2b and absorbs radio waves. The resin support portion 3c can adjust the distance from the radio wave absorber 3b to the high-frequency amplifier 2b by adjusting the position of the radio wave absorber 3b with respect to the housing 3a.

According to such a high-frequency package 3, it is possible to adjust the distance from the high-frequency amplifier 2b to the radio wave absorber 3b by adjusting the position of the radio wave absorber 3b with respect to the housing 3a by using the resin support portion 3c. Therefore, according to the high-frequency package 3 of the present embodiment, it is possible to improve the radio wave absorption characteristic by enabling adjustment of the distance from the high-frequency amplifier 2b to the radio wave absorber 3b.

Moreover, according to the high-frequency package 3, since the distance from the high-frequency amplifier 2b to the radio wave absorber 3b can be adjusted, even if the high-frequency amplifier 2b is replaced, the distance from the high-frequency amplifier 2b to the radio wave absorber 3b can be optimized. Accordingly, the high-frequency package 3 can be used for the high-frequency amplifier 2b driven at different frequencies. As a result, according to the high-frequency package 3, it is not necessary to have a different structure for each type of the high-frequency amplifier 2b, and so standardization of components becomes possible.

Further, in the high-frequency package 3 of the present embodiment, the resin support portion 3c is press-fitted into the through hole 3a2 provided in the housing 3a, whereby the radio wave absorber 3b is fixed. That is, the adjusting means for adjusting the position of the radio wave absorber 3b with respect to the housing 3a is constituted by the resin support portion 3c, to which the radio wave absorber 3b is fixed, being press-fitted into the through hole 3a2 provided in the housing 3a. Therefore, the resin support portion 3c passes through the housing 3a, and the resin support portion 3c can be moved from the outside of the housing 3a.

The high-frequency module 1 of the present embodiment is provided with the printed wiring substrate 2a, the high-frequency amplifier 2b mounted on the printed wiring substrate 2a, and the high-frequency package 3. By enabling adjustment of the distance from the high-frequency amplifier 2b to the radio wave absorber 3b as described above, according to the high-frequency package 3, the radio wave absorption characteristic can be improved. Therefore, according to the high-frequency module 1 provided with such a high-frequency package 3, it is possible to improve the performance by improving the radio wave absorption characteristic.

Further, the radio wave absorption method of the present embodiment, by adjusting the position of the radio wave absorber 3b that absorbs radio waves with respect to the housing 3a that shields the radio waves radiated from the high-frequency amplifier 2b, adjusts the distance from the radio wave absorber 3b to the high-frequency amplifier 2b.

The radio wave absorption method of the present embodiment as described above adjusts the distance from the high-frequency amplifier 2b to the radio wave absorber 3b by adjusting the position of the radio wave absorber 3b with respect to the housing 3a. Therefore, the radio wave absorption method of the present embodiment can improve the radio wave absorption characteristic by enabling adjustment of the distance from the high-frequency amplifier 2b to the radio wave absorber 3b.

### Second Embodiment

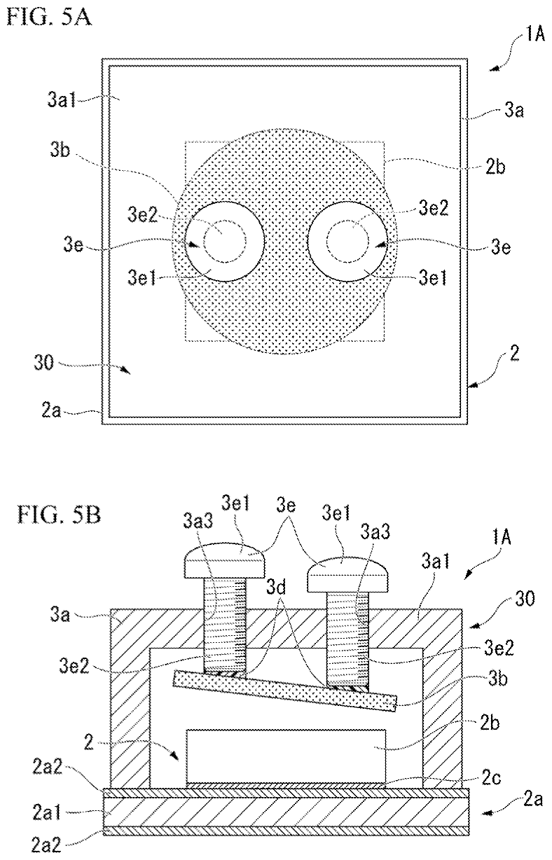

Next, the second embodiment of the present disclosure will be described with reference to FIGS. 5A and 5B. Note that in the description of the present embodiment, descriptions of the same portions as the first embodiment are omitted or simplified.

FIGS. 5A and 5B are schematic outline block diagrams of the high-frequency module 1A of the present embodiment. FIG. 5A is a plan view and FIG. 5B is a vertical sectional view. As shown in FIGS. 5A and 5B, the present embodiment includes a high-frequency package 30 in place of the high-frequency package 3 of the first embodiment.

The high-frequency package 30 is provided with a housing 3a, a radio wave absorber 3b, and two (plural) screws 3e (adjusting means). In this embodiment, two screw holes 3a3 are provided in the upper wall 3a1 of the housing 3a. These screw holes 3a3 are through holes into which the screws 3e are screwed, and are provided with screw grooves on the inner peripheral surface thereof.

The two screws 3e are arranged in a direction orthogonal to the vertical direction. For convenience of explanation, the direction in which the screws 3e are arranged is referred to as a left-right direction. That is, in the present embodiment, as shown in FIGS. 5A and 5B, there is the screw 3e arranged on the left side and the screw 3e arranged on the right side.

Each screw 3e has a head portion 3e1 and a shaft portion 3e2. The head portion 3e1 is connected to the upper end of the shaft portion 3e2. For example, the head portion 3e1 is provided with a groove (not shown) into which a driver is fitted. The shaft portion 3e2 is a rod-shaped portion having a thread groove formed on the peripheral surface thereof. The shaft portion 3e2 is screwed into the screw hole 3a3. Each of the screws 3e can be moved in the vertical direction with respect to the housing 3a by rotating the shaft portion 3e2 about the axis thereof. That is, the screw 3e is screwed into the screw hole 3a3 provided in the housing 3a in an insertable and removable manner.

The radio wave absorber 3b is fixed to the lower ends of these screws 3e via an adhesive layer 3d. The position of each screw 3e with respect to the housing 3a can be adjusted individually as shown in FIG. 5B. Therefore, in the present embodiment, it is possible to tilt the radio wave absorber 3b with respect to the high-frequency amplifier 2b by changing the positions in a vertical direction of the right-side portion and the left-side portion of the radio wave absorber 3b.

That is, in the present embodiment, it is possible to change the distance from the right-side portion of the radio wave absorber 3b to the high-frequency amplifier 2b and the distance from the left-side portion of the radio wave absorber 3b to the high-frequency amplifier 2b.

In the high-frequency package 30 of the present embodiment, the adjusting means for adjusting the position of the radio wave absorber 3b with respect to the housing 3a is constituted by the screw 3e. That is, the adjusting means has the screw 3e that can be inserted and removed into the screw hole 3a3 provided in the housing 3a. According to the high-frequency package 30 of the present embodiment as described above, the position of the radio wave absorber 3b can be easily adjusted by rotating the screw 3e. Further, fine adjustment of the position of the radio wave absorber 3b can be easily carried out.

In the high-frequency package 30 of the present embodiment, a plurality of the screws 3e are provided, with the radio wave absorber 3b being connected to the tip ends of the plurality of screws 3e. Therefore, the radio wave absorber 3b can be tilted with respect to the high-frequency amplifier 2b, and the distance from the right-side portion of the radio wave absorber 3b to the high-frequency amplifier 2b and the distance from the left-side portion of the radio wave absorber 3b to the high-frequency amplifier 2b can be changed.

For example, it is conceivable to install a high-frequency component capable of inputting two alternating current (AC) signals of a frequency converter, etc., and outputting a signal having a sum or difference frequency between them. In such a high-frequency component, the higher the frequency, the shorter the phase, and the lower the frequency, the longer the phase. Therefore, it is preferable to arrange the radio wave absorber 3b at a position suitable for each of the input and output of the high-frequency component. According to the high-frequency package 30 of the present embodiment, by tilting the radio wave absorber 3b, it is possible to arrange the radio wave absorber 3b at a position suitable for each of the input and output of the high-frequency component.

In the present embodiment, a configuration using two screws 3e has been described. However, the present disclosure is not limited thereto. For example, it is possible to adopt a configuration using three or more screws 3e.

### Third Embodiment

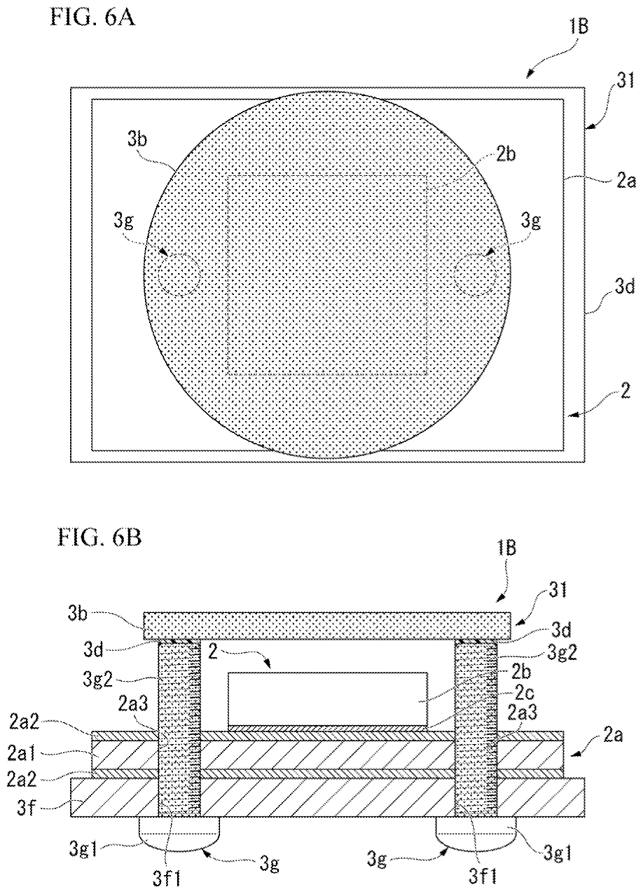

Next, the third embodiment of the present disclosure will be described with reference to FIGS. 6A and 6B. Note that in the description of the present embodiment, descriptions of the same portions as the first embodiment are omitted or simplified.

FIGS. 6A and 6B are schematic outline block diagrams of the high-frequency module 1B of the present embodiment. FIG. 6A is a plan view and FIG. 6B is a vertical sectional view. As shown in FIGS. 6A and 6B, the present embodiment is provided with a high-frequency package 31 in place of the high-frequency package 3 of the first embodiment.

The high-frequency package 31 is provided with a radio wave absorber 3b, a shielding plate 3f, and two (plural) screws 3g. The shielding plate 3f is arranged under the printed wiring substrate 2a (substrate). That is, the shielding plate 3f is arranged on the back surface side of the mounting surface of the high-frequency amplifier 2b of the printed wiring substrate 2a.

The shielding plate 3f is formed of, for example, metal, and is a radio wave shielding portion that shields radio waves. In the present embodiment, the shielding plate 3f is formed in a plate shape. The shielding plate 3f is provided with two screw holes 3f1. These screw holes 3f1 are through holes into which the screws 3g are screwed, and are provided with screw grooves on the inner peripheral surface thereof.

Further, in the present embodiment, the printed wiring substrate 2a is also provided with two screw holes 2a3. These screw holes 2a3 are arranged at positions overlapping with the screw holes 3f1 of the shielding plate 3f when viewed from above. These screw holes 3f1 are through holes into which the screws 3g are screwed, and are provided with screw grooves on the inner peripheral surface thereof.

The two screws 3g are arranged in a direction orthogonal to the vertical direction. For convenience of explanation, the direction in which the screws 3g are arranged is referred to as a left-right direction. That is, in the present embodiment, as shown in FIGS. 6A and 6B, the screw 3g is arranged on the left side and the screw 3g on the right side.

Each screw 3g has a head portion 3g1 and a shaft portion 3g2. The head portion 3g1 is connected to the lower end of the shaft portion 3g2. For example, the head portion 3g1 is provided with a groove (not shown) into which a driver is fitted. The shaft portion 3g2 is a rod-shaped portion having a threaded groove formed on the peripheral surface thereof. The shaft portion 3g2 is screwed into the screw hole 3f1 and the screw hole 2a3. Each of the screws 3g can be moved in the vertical direction with respect to the shielding plate 3f by rotating the shaft portion 3g2 about the axis thereof. That is, each screw 3g is screwed into the screw hole 3f1 provided in the shielding plate 3f and the screw hole 2a3 provided in the printed wiring substrate 2a in an insertable and removable manner. These screws 3g are arranged so as to pass through the printed wiring substrate 2a from the back surface side of the mounting surface.

The radio wave absorber 3b is fixed to the upper ends of these screws 3g via an adhesive layer 3d. The radio wave absorber 3b is arranged above the high-frequency amplifier 2b. By adjusting the position of each screw 3g with respect to the shielding plate 3f, the position of the radio wave absorber 3b with respect to the shielding plate 3f is adjusted, and the distance from the radio wave absorber 3b to the high-frequency amplifier 2b can be adjusted.

Further, at least the surface layer of the shaft portion 3g2 of each screw 3g is formed using a magnetic material, enabling absorption of radio waves. That is, in this embodiment, the screw 3g has a radio wave absorbing function. Therefore, it is possible to absorb radio waves even with the screw 3g arranged in the vicinity of the high-frequency amplifier 2b. The shaft portion 3g2 may be entirely formed of a magnetic material. The surface layer of the shaft portion 3g2 may be formed using a magnetic material, while the central portion surrounded by the surface layer may be formed using another material. Moreover, the head portion 3g1 of the screw 3g can also be formed using a magnetic material.

In the high-frequency package 31 of the present embodiment, an adjusting means for adjusting the position of the radio wave absorber 3b with respect to the shielding plate 3f is constituted by the screw 3g. That is, the adjusting means has the screw 3g that can be inserted into and removed from the screw hole 3f1 provided in the shielding plate 3f According to the high-frequency package 31 of the present embodiment, the position of the radio wave absorber 3b can be easily adjusted by rotating the screw 3g. Fine adjustment of the position of the radio wave absorber 3b can also be easily performed.

Further, in the high-frequency package 31 of the present embodiment, a plurality of the screws 3g are provided, with the radio wave absorber 3b being connected to the tip end of each of the plurality of screws 3g. Therefore, the radio wave absorber 3b can be tilted with respect to the high-frequency amplifier 2b, and the distance from the right-side portion of the radio wave absorber 3b to the high-frequency amplifier 2b and the distance from the left-side portion of the radio wave absorber 3b to the high-frequency amplifier 2b can be changed.

In the present embodiment, a configuration using two of the screws 3g has been described. However, the present disclosure is not limited thereto. For example, it is also possible to adopt a configuration using three or more of the screws 3g.

Moreover, in the present embodiment, the shielding plate 3f is formed in a plate shape, and the sides of the high-frequency amplifier 2b are open. For this reason, it is possible to prevent heat from being trapped around the high-frequency amplifier 2b, thereby improving heat dissipation efficiency.

According to the present embodiment as described above, the radio wave absorber 3b can be arranged to face a high-frequency component even when a high-frequency component is used for which a container-shaped housing cannot or need not be arranged.

### Fourth Embodiment

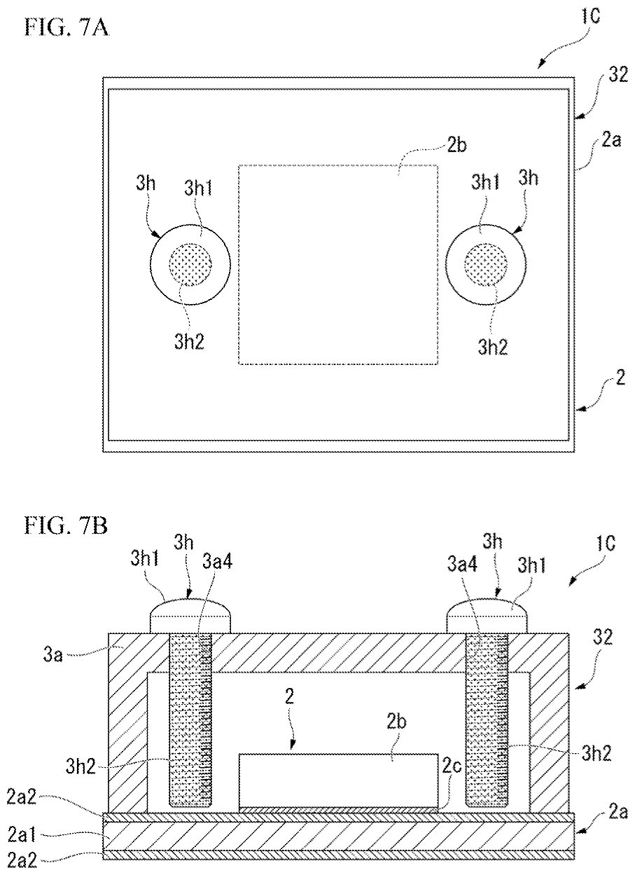

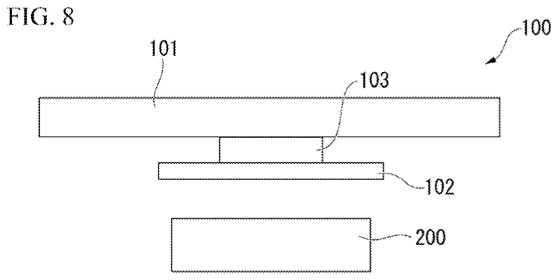

Next, the fourth embodiment of the present disclosure will be described with reference to FIGS. 7A and 7B. Note that in the description of the present embodiment, descriptions of the same portions as the first embodiment are omitted or simplified.

FIGS. 7A and 7B are schematic outline block diagrams of the high-frequency module 1C of the present embodiment. FIG. 7A is a plan view and FIG. 7B is a vertical sectional view. As shown in FIGS. 7A and 7B, the present embodiment is provided with a high-frequency package 32 in place of the high-frequency package 3 of the first embodiment.

The high-frequency package 32 is provided with a housing 3a and two screws 3h. In the present embodiment, two screw holes 3a4 are provided in the upper wall 3a1 of the housing 3a. The screw holes 3a4 are through holes into which the screws 3h are screwed, and are provided with screw grooves on the inner peripheral surface thereof.

The two screws 3h are arranged in a direction orthogonal to the vertical direction. For convenience of explanation, the direction in which the screws 3h are arranged is referred to as a left-right direction. That is, in the present embodiment, as shown in FIGS. 7A and 7B, the screw 3h is arranged on the left side and the screw 3h arranged on the right side.

Each screw 3h has a head portion 3h1 and a shaft portion 3h2. The head portion 3h1 is connected to the upper end of the shaft portion 3h2. For example, the head portion 3h1 is provided with a groove (not shown) into which a driver is fitted. The shaft portion 3h2 is a rod-shaped portion having a threaded groove formed on the peripheral surface thereof. The shaft portion 3h2 is screwed into the screw hole 3a4. These screws 3h can be moved in the vertical direction with respect to the housing 3a by rotating the shaft portion 3h2 around the axis thereof. That is, the screw 3h is screwed into the screw hole 3a4 provided in the housing 3a in an insertable and removable manner.

Further, at least the surface layer of the shaft portion 3h2 of the screw 3h is formed using a magnetic material, enabling absorption of radio waves. That is, in the present embodiment, the screw 3h has a radio wave absorbing function, such that the radio wave absorber is integrated with the screw 3h. Note that the shaft portion 3h2 may be entirely formed of a magnetic material. Also, the surface layer of the shaft portion 3h2 may be formed using a magnetic material while the central portion surrounded by the surface layer may be formed using another material. Moreover, the head portion 3h1 of the screw 3h can also be formed using a magnetic material.

According to the high-frequency package 32 of the present embodiment, the distance between the shaft portion 3h2 of the screw 3h and the high-frequency amplifier 2b can be adjusted by adjusting the position in the vertical direction of the screw 3h with respect to the housing 3a.

Also, in the present embodiment, since the radio wave absorber is integrated with the screw 3h, it is not necessary to separately install a radio wave absorber. Therefore, it is possible to simplify the structure of the high-frequency package 32.

In the present embodiment, the shaft portion 3h2 of the screw 3h that functions as a radio wave absorber can be arranged close to the printed wiring substrate 2a. Therefore, it is also possible to absorb radio waves radiated from the conductor layer 2a2 of the printed wiring substrate 2a.

### Fifth Embodiment

Next, the fifth embodiment of the present disclosure will be described with reference to FIG. 8. FIG. 8 is a schematic outline block diagram of the high-frequency package 100 of the present embodiment. The high-frequency package 100 is provided with a radio wave shielding unit 101 that shields radio waves radiated from a high-frequency component 200, a radio wave absorber 102 that is arranged facing the high-frequency component 200 and absorbs radio waves, and an adjusting means 103 that can adjust the distance from the radio wave absorber 102 to the high-frequency component 200 by adjusting the position of the radio wave absorber 102 with respect to the radio wave shielding unit 101.

According to the high-frequency package 100 of the present embodiment, the distance from the high-frequency component 200 to the radio wave absorber 102 can be adjusted by adjusting the position of the radio wave absorber 102 with respect to the radio wave shielding portion 101 by using the adjusting means 103. Therefore, according to the high-frequency package 100 of the present embodiment, it is possible to improve the radio wave absorption characteristic by enabling adjustment of the distance from the high-frequency component 200 to the radio wave absorber 102.

As stated above, a radio wave absorber formed by using a magnetic material has been disclosed. A radio wave absorber formed using a magnetic material obtains an absorption loss by taking in a magnetic field and converting it to heat. By appropriately adjusting the distance from the radiation source of the radio waves, such a radio wave absorber can obtain a high absorption characteristic of radio waves on the basis of the wave canceling action with a reflected wave having a phase difference. Therefore, the distance from the radiating source to the radio wave absorber by which a high absorption characteristic can be obtained depends on the phase of the wavelength of the radio wave and generally changes depending on the frequency of the radio wave. Therefore, for example, when the operating frequency is changed by replacing the high-frequency component, it is necessary to adjust the distance from the radiating source to the radio wave absorber by changing the thickness of the radio wave absorber or the wall thickness of the housing, for example. For this reason, it becomes necessary to redesign the housing, and management becomes complicated due to the increase in the types of high-frequency packages. In addition, it has not been easy to fine-tune the distance from the high-frequency component to the radio wave absorber.

According to the present disclosure, it is possible to improve the radio wave absorption characteristic by making it possible to adjust the distance from the high-frequency component to the radio wave absorber.

While preferred embodiments of this disclosure have been described and illustrated above, it should be understood that these are exemplary of this disclosure and are not to be considered as limiting. Additions, omissions, substitutions, and other modifications can be made without departing from the spirit or scope of this disclosure. Accordingly, this disclosure is not to be considered as being limited by the foregoing description, and is only limited by the scope of the appended claims.

What is claimed is:

1. A high-frequency package comprising:
a radio wave shielding portion that shields radio waves radiated from a high-frequency component;
a radio wave absorber that is arranged facing the high-frequency component and absorbs the radio waves; and
an adjusting means that enables adjustment of distance from the radio wave absorber to the high-frequency component by adjusting a position of the radio wave absorber with respect to the radio wave shielding portion.

2. The high-frequency package according to claim 1, wherein the adjusting means comprises a resin portion that is press-fitted into a through hole provided in the radio wave shielding portion and to which the radio wave absorber is fixed.

3. The high-frequency package according to claim 1, wherein the adjusting means comprises a screw that can be inserted into and removed from a screw hole provided in the radio wave shielding portion.

4. The high-frequency package according to claim 3, further comprising a plurality of the screws,
wherein the radio wave absorber is connected to tip ends of the plurality of screws.

5. The high-frequency package according to claim 4, wherein
the radio wave shielding portion is arranged on a back surface side of a mounting surface of a substrate on which the high-frequency component is mounted; and
the screws are arranged passing through the substrate from the back surface side.

6. The high-frequency package according to claim 3, wherein the screw includes the radio wave absorber, and the radio wave absorber and the adjusting means are integrated.

7. A high-frequency module comprising:
a substrate;
a high-frequency component mounted on the substrate; and
a high-frequency package,
wherein the high-frequency package comprises:
a radio wave shielding portion that shields radio waves radiated from the high-frequency component;
a radio wave absorber that is arranged facing the high-frequency component and that absorbs the radio waves; and
an adjusting means that enables adjustment of distance from the radio wave absorber to the high-frequency component by adjusting a position of the radio wave absorber with respect to the radio wave shielding portion.

8. A radio wave absorption method comprising:
adjusting distance from a radio wave absorber that absorbs radio waves to a high-frequency component by adjusting a position of the radio wave absorber with respect to a radio wave shielding portion that shields the radio waves radiated from the high-frequency component.
